(19) United States
(12) Patent Application Publication
(10) Pub. No.: US 2003/0212937 A1
(43) Pub. Date: Nov. 13, 2003

(54) System and method for exposing state based logic signals within an electronics system over an existing network conduit

(76) Inventors: Marc Todd, Foxboro, MA (US); Jesse D. Beeson, Franklin, MA (US); James Welch, Mashpee, MA (US)

Correspondence Address: LACASSE & ASSOCIATES, LLC, 1725 DUKE STREET, SUITE 650, ALEXANDRIA, VA, 22314, US

(21) Appl. No.: 10/139,290

(22) Filed: May 7, 2002

(51) Int. Cl. G01R 31/28

(52) U.S. Cl. 714/724

(57) ABSTRACT

State-based logic signals are exposed within an electronic system (such as semiconductors, single board systems or multi board systems) via an existing system network conduit (Ethernet, USB, or other packet-based architectures), in or out-of-band, communicating with a logic capture device. State-based logic data is transported as packets over the existing system network interface to a device that filters and switches on these particular packets and presents the packet payload to the logic analysis device using the appropriate electrical or optical interface.

### BACKGROUND OF THE INVENTION

1. Field of Invention

The present invention relates generally to the field of debugging electronic systems. More specifically, the present invention is related to debugging electronic embedded systems.

2. Discussion of Prior Art

Many modern electronic systems, including semiconductors, single-board and multi-board systems, contain a multitude of asynchronous processing engines based on higher logic. There is little ability to gain visibility into the state of the logic in a timely manner due to enormous data rates and the inability of these systems to get the state-based logic data out of the system.

Some common prior art schemes used for debugging such embedded systems include dedicated out-of-band technologies (i.e., schemes wherein a channel is used exclusively to exchange state based logic data) such as joint test action group (JTAG) based debugging and trace ports debugging. Such schemes access and debug (via, for example, a serial interface) integrated circuits, such as: microprocessors, digital signal processors (DSPs), application-specific integrated circuits (ASICs), and complex programmable logic devices (CPLDs).

Traditional debug and trace transportation methodologies, however, are unable to accommodate transporting sampled state based logic data out of deeply embedded systems. This lack of transportation scalability creates a void between the electronic system and the logic analysis devices designed to analyze logic events for the express purpose of debugging programmable logic, hardware, and/or software.

Moreover, with recent technological advances, the rates of logic flux within electronic systems are increasing exponentially and processing engines are becoming deeply embedded into the silicon. The rates, at normal operation, are becoming so fast that the inspection of the system operation changes their state. Thus, technologies like JTAG and trace ports offer the user the ability to control and inspect areas of the system, but are limited as to the amount of sampled logic data these transport channels can pass out of the electronic systems. Additionally, traditional inspection of the buses between semiconductors in a system is limited to the pins and lines exposed by the system designer. In many cases, the semiconductors themselves do not expose buses (or other traditional logic inspection points) between logic entities, thus rendering this technique unusable. Such busses include those between a CPU and a cache memory and/or between multiple CPU cores within a chip.

Many of the newer semiconductors also contain some form of FPGA technology that allows the system designer to create hundreds of asynchronous logic events that run at great speeds. These semiconductors can also have multiple processor cores designed to execute a large number of op-codes or higher logic instructions, all of which need access to debug exposure. The overall cost for a dedicated out-of-band solution for even one core may not be feasible, much less several cores and logic events with differing logic sampling requirements.

Due to the complexity of programming logic, hardware and/or software, engineers need the ability to capture the changing states of the electronic system as it responds to the program written by the engineer. There are several basic inspection techniques used by the engineer to debug his programming logic.

In the first case, the engineer needs to record all state changes as the system executes his program and/or logic. In this case, the engineer may be monitoring to ensure proper operation of the system.

In the second case, the engineer may be interested in looking at sampled logic states of a system. This technique is good for inspecting performance analysis or quick monitoring of the logic state to see if the system is in the correct state.

In a third case, the engineer may need to stimulate a system to move to the next state or a new state altogether. This is done by sending a message to the system to move to the appropriate state.

Given the nature of these base debug techniques from which higher level debug analysis is derived, current debugging schemes with sampled state-based logic data fail to provide for a transport solution that accommodates the nature of these techniques as electronic systems increase in speed, complexity, and reduced visibility. Additionally, dedicated out-of-band debug/trace solutions are often not able to scale in bandwidth (due to resource limitations or unavailability of external logic analysis systems at higher speeds), and such systems often interfere with the performance of the system (as debugging the behavior of the system modifies the behavior of the system), thereby making system operation and problems difficult to track.

Furthermore, given the realities of debug cost versus feature cost, debugging will always be secondary to adding features to a system. Debugging has a limited use in the lifecycle of a system; and once the programming logic is operational, debugging may never be used in that system again. Thus, sampled state-based logic data transport solutions that use dedicated out-of-band solutions will be at constant odds with the cost structure and economics of the electronics system.

Also, during a product life cycle, much time is spent attempting to recreate observed problems. Sometimes this is relatively straightforward. Oftentimes the problems or events are intermittent, requiring excessive amounts of time to recreate and hunt down the source of the event or problem. Worse yet, sometimes a problem can never be recreated until it hits the customer's site. One alternative for this issue in prior art systems is to maintain a log file in software to track an application's movement. But this approach does not typically extend to system level software or the driver level. Thus, if the system crashes, there is a good chance that the log file may not be up to date, be corrupted, or be lost entirely.

Whatever the precise merits, features, and advantages of the above-mentioned prior art debugging schemes, none of them achieve or fulfill the benefits of the present invention.

### SUMMARY OF THE INVENTION

The present invention provides for an electronic embedded system comprising an embedded debug/trace component sampling system-level state-based logic data and an existing network conduit packetizing and transmitting to an external system said sampled system-level state-based logic data. In one embodiment, the transmission is done in-band by sharing transmission bandwidth between the system-level state-based logic data and application-level data associated with the embedded system. In another embodiment, the transmission is done out-of-band by dedicating transmission bandwidth for transmitting the packetized sampled system-level state-based data.

The present invention also allows for controlling an embedded system via a controller, wherein the controller receives, via a first interface, control instructions from an external system to modify system-level state-based logic data associated with the electronic embedded system, and transmits, via a second interface, the received control instructions to the electronic embedded system via the network conduit.

### BRIEF DESCRIPTION OF THE DRAWINGS

FIG. 1 illustrates a system according to the principles of the present invention for debugging program logic, hardware, and/or software.

FIG. 2 illustrates an internal block diagram of the filter device of FIG. 1.

FIG. 3 illustrates a system block diagram showing a control device that is used to set parameters, modify data, etc., in the device under test.

### DESCRIPTION OF THE PREFERRED EMBODIMENTS

While this invention is illustrated and described in a preferred embodiment, the invention may be produced in many different configurations, forms, and materials. There is depicted in the drawings, and will herein be described in detail, a preferred embodiment of the invention, with the understanding that the present disclosure is to be considered an exemplification of the principles of the invention and the associated functional specifications for its construction and is not intended to limit the invention to the embodiment illustrated. Those skilled in the art will envision many other possible variations within the scope of the present invention.

Many electronic systems, such as, manufacturing process control, personal computers, embedded computers, test and measurement, telecommunications, and local area network support systems, having existing layer-2 style network conduits in order to allow their application level software to communicate with external devices. That is, a layer-2 style network conduit is part of the system's main feature set. The present invention uses these existing network conduits to deliver sampled state-based logic out of such systems.

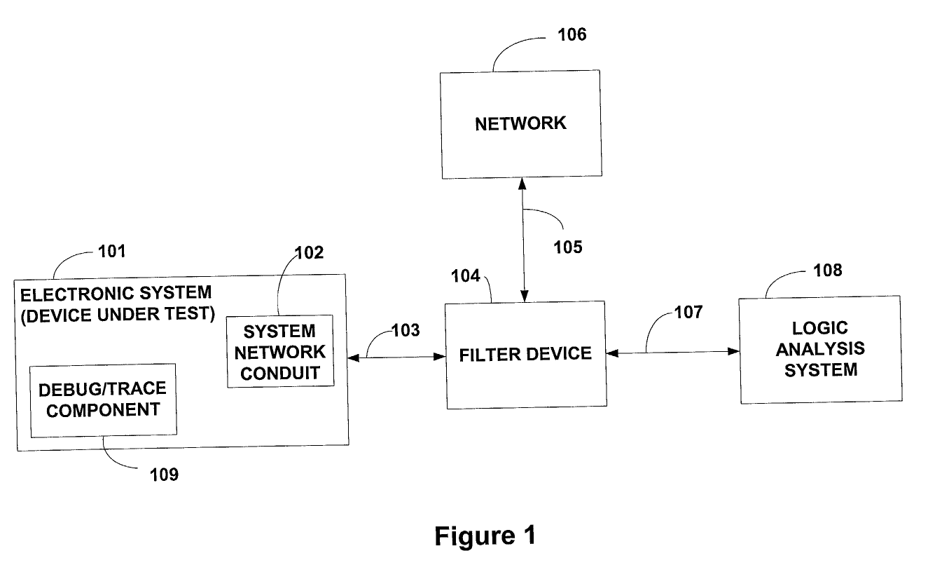

FIG. 1 illustrates a system according to the principles of the present invention for debugging program logic, hardware, and/or software. The system comprises a device under test (DUT) 101, a filter device 104, and a logic analysis system 108. The DUT 101 has an existing network conduit 102 capable of communicating via a packet-based network with filter device 104. Moreover, the filter device 104 is able to communicate with both the logic analysis system 108 and an external network 106. A debug/trace component 109 on an electronic system is part of the DUT 101's final design. Debug/Trace component 109 samples state-based logic of DUT 101 and uses the existing network conduit 102 to pass the sampled state-based logic data out of DUT 101. While the bulk of network conduit bandwidth is dedicated to application level software, a variable portion may be dedicated to the debug/trace component 109. Thus, application level software and the debug/trace component 109 can share a common transport. In one embodiment, a quality of service metering scheme is implemented wherein the scheme allows for controlling traffic priority relative to native applications, or other in-band applications. As network conduit bandwidth increases for application level use, the available bandwidth for system level (debug/trace) software increases simultaneously. Additionally, it should be noted that a pure hardware, a pure software, and a hybrid hardware/software implementation of the debug/trace component is envisioned and should not be used to limit the scope of the present invention.

The device under test (DUT) 101, for example, can be as small as a semiconductor or as complex as a multi-board system. The engineer sets up the DUT 101 to run a series of higher-level logic state sequences to perform a particular task. The logic analysis system 108 is used to monitor these logic state changes and show the engineer if the logic of the DUT 101 is operating as expected. Furthermore, it shows where, in particular, the error in logic design may be so that the engineer can fix the problem and re-test.

Packetized sampled logic data is passed through existing network conduit 102 via an in-band (sharing transmission bandwidth along with other network traffic) or out-of-band (dedicated bandwidth) transmission scheme using appropriate electrical or optical interface cable 103. The DUT 101 can have many sample and collection logic points in it that get forwarded out the network conduit 102. The network conduit 102 supports packet based transmission of data, wherein the transmission is done over a layer 2-style (based on the OSI model for point-to-point connections containing specifications for frames, synchronization, and error control) transmission protocol. Protocols that support such packet-based transmission include, but are not limited to, 802.3 (Ethernet), USB, ATM, SONET, 802.11, Fibre-channel, Firewire or 1394, Infiniband, Bluetooth, 802.15, 802.16, or 802.17.

It should be noted that sampled logic data as described in this specification generically refers to much more than sampled internal hardware signal nodes (traditional hardware logic analysis). The sampled logic data may be provided by system software in concert with hardware signal capture or by itself. The software may provide such data as memory snapshots, counter values, internal system variables, etc. The logic data packets can also contain processor op-code execution flow associated with a plurality of processors that are asynchronous or synchronous processing units that are independent of or dependent on op-code instructions to be measured by trace logic analysis system 108, software, and/or hardware.

Additionally, the rate of sampling such logic data can be reduced to decrease the load of sampled logic data packets on the network conduit 102. In another scenario, the amount of sampled logic data packets can be scaled linearly with the available network interface bandwidth. Moreover, the system of the present invention, being preferably bidirectional, allows for modification of such data. The low-level system software can be monitored and adjusted non-invasively while the system is in full operation. This capability facilitates both debugging and tracing during system development as well as remotely, once deployed.

It should also be noted that the logic data packets can contain timestamp and ordering data that can be post-processed by the logic analysis system 108, other hardware, and/or software. Furthermore, the sampled logic data packets can be compressed before transmission via the network conduit 102. In this scenario, the filter device 104, logic analysis system 108, or other hardware/software systems can decode these compressed packets.

Upon reception of such sampled state-based logic, the filter device 104 filters these sampled logic packets based on network type and redirects the contents of the data out to the logic analysis system 108 over the appropriate electrical or optical interface 107 to the logic analysis system 108. All other network traffic coming into the filter device 104 from the DUT 101, through the network conduit 102, over the appropriate electrical or optical interface 103, will be packet forwarded to the network 106 over the appropriate electrical or optical interface 105.

Consequently, all other network traffic coming into the filter device 104 from the network 106 over the appropriate electrical or optical interface 105 will be packet forwarded to the DUT 101 through the network conduit 102 over the appropriate electrical or optical interface 103.

In one embodiment, the system shown in FIG. 1 includes an encoder for encoding the packetized data before transmission. Some examples of encoding include (but are not limited to) encryption (such as for security), compression, or code format conversion (e.g., convert data in an ASCII format for readability).

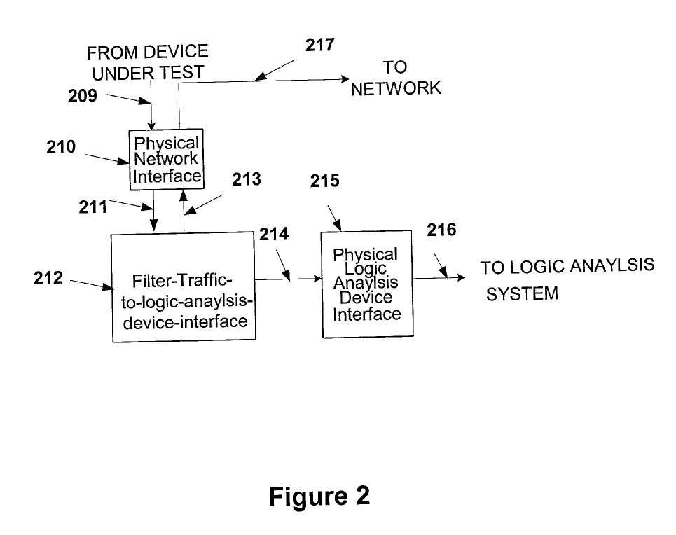

FIG. 2 shows the internal block diagram of the filter device 104 of FIG. 1. All packets from the DUT (101 of FIG. 1) enter the filter system (104 of FIG. 1) over the appropriate electrical or optical interface 209 through the physical network interface 210 and over the internal bus 211 to the filter unit 212 which processes the packets. Any packets that have a type field that indicates the packet contains sampled state-based logic data in the payload gets converted and forwarded over a bus 214 to the physical logic analysis interface 215 and on to the logic analysis device (208 of FIG. 1) over the appropriate electrical or optical interface 216.

All other packets that do not match the sampled state based logic data type field in the filter unit 212 get forwarded back to the physical interface unit 210 over the internal bus 213. The physical interface unit 210 then sends that packet over the appropriate electrical or optical interface 217 to the network.

Thus, the filter unit 212 filters the network packets of state-based logic data, records statistics, and presents the logic data payload to the logic analysis system (108 of FIG. 1) using the appropriate electrical or optical interface to the logic analysis device. For example, the filter unit can monitor various software variables and calculate standard statistical values (such as the expected value) associated with such variables. When the debugging phase of the electronic system lifecycle is over, the electronic system can reclaim all of the network conduit bandwidth for other feature uses. In an exemplary embodiment, designers and engineers have the choice of permanently allocating a small portion of the network conduit's bandwidth for monitoring of a deployed product/system. The use of an existing network conduit for transportation of state-based logic data provides the ability for remote debugging/monitoring/tuning; something a dedicated out-of-band solution would be hard pressed to provide. Additionally, providing a scalable bandwidth debugging/tracing solution allows the engineers to choose the level of system impact according to the debugging/tracing task at hand.

Although FIGS. 1 and 2 illustrate a system designed to request and receive sampled state-based logic data via network packets, it should be noted that the present invention's system is preferably bi-directional, allowing for modification of data (such as memory snapshots, counter values, internal system variables, etc.).

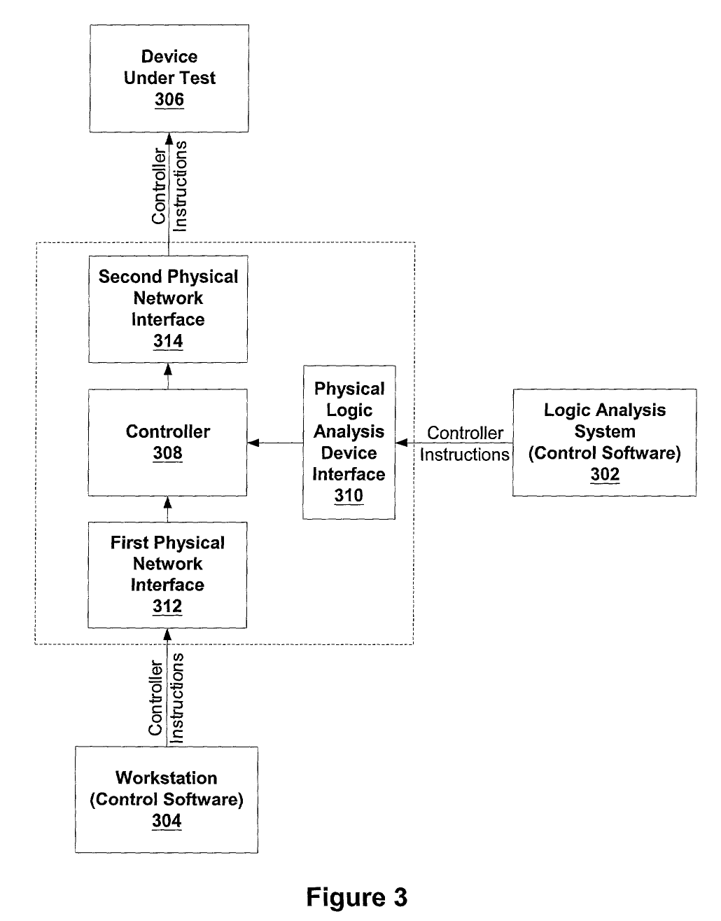

FIG. 3 illustrates a system block diagram showing a control device that is used to set parameters, modify data, etc., in the DUT. In this scenario, a control device (such as a logic analysis system 302 or a workstation 304) is used to modify parameters associated with a DUT 306 via a graphical user interface (GUI) implementing control software. For example, the control software can be used to set a watermark value and, upon execution of a series of steps, the effect on the DUT can be monitored. It should be noted that the control software can be located in any device external to the DUT as long as the external device is able to access a network conduit for transmitting instructions for modifying any parameters associated with the DUT. For example, the control software can reside in devices such as the logic analysis system 302 or workstation 304, wherein such devices transmit instructions (for modifying parameters associated with the DUT 306) via interfaces 310 physical logic analysis device interface) and 312 (first physical network interface), respectively. Interfaces 310 and 312, in turn, forward such instructions to controller 308. Next, controller 308 forwards such instructions to DUT 306 via a second physical network interface 314.

It should be noted that various kinds of interfaces can be used for establishing a packet-based communication session between the external devices (302 or 304) and the controller 308, such as (but not limited to) a gigabit network controller or a standard 10/100 MBit/s network interface card. Moreover, one skilled in the art can envision using various current and future interfaces and, hence, the type of packetized network interface used should not be used to limit the scope for the present invention.

Additionally, FIG. 3 shows a simplified flow diagram illustrating the flow of control data from the external devices (302 or 304) to the DUT 306, but it should be noted that the communication channel between the external device and the DUT is preferably a bidirectional communication channel allowing for both the transmission of control data and the reception of debug-related data. It should be noted that the filter device does not have to be dedicated hardware; it may be a software application on a PC, for instance, utilizing a network interface card NIC). Also, the filter of FIG. 2 and the controller of FIG. 3 (including various physical network interfaces) may be implemented as a single device. Furthermore, the logic analysis system can be implemented via software that can be run on workstation 304. In this scenario, the software implementing the logic analysis system and the workstation 304 share a common network interface 312 to communicate with the controller 308.

In one embodiment, bandwidth for the transportation of sampled state based logic data is allocated in an “on-demand” fashion, wherein full channel (network conduit) bandwidth is allocated and available to the application. Hardware can track nearly anything, such as the last N-events or instructions executed, storing it in a circular buffer. Thus, when a critical event occurs such as application or system crash, debug bandwidth would be allocated “on-demand” to report the tracking information leading up to the critical event to the filter/logic analysis device through the proposed existing network conduit. Having pertinent information about what the system was doing (not only at the time of the critical event but leading up to it as well) presented “on-demand” at the time of the critical event is very powerful. Having this information greatly reduces the “hunting” time required to identify the cause of the critical event. This information could be gathered remotely as well, given the network conduit.

In an exemplary embodiment, the “on-demand” channel allocation for debugging is realized in the hardware. Hardware has the ability to closely track the interaction of CPU cores as well as microcode engines. Microcode engines are very difficult to debug, being heavily embedded by definition. Many microcode engines are present for the network conduit, as they already have the network conduit in place. Having pertinent information such as microcode program flow and register values leading up to the critical event can be priceless. Furthermore, adding an “on-demand” network conduit debug bandwidth for software increases debug usability over a standard log file. Although, a hardware “on demand” approach is outlined in the above-described embodiment, it should be noted that a software “on demand” based approach, or a mixed software/hardware based approach, is also envisioned.

One example of a hardware approach would be monitoring a processor core execution flow. When a fatal exception occurs, this trace information could be transmitted “on-demand” to the logic analysis device. One example of a purely software approach would be the monitoring of a counter variable (perhaps an error count), when it exceeds a threshold information from the software could be sent “on-demand” to the logic analysis device. One example of a hybrid hardware / software approach would be to have a software counter variable trigger the hardware-tracked processor execution flow information to be sent “on-demand” to the logic analysis device.

One implementation of an “On-demand” Quality of Service algorithm would be to send the state-based logic data whenever there is any available. Thus, the application retains full use of the bandwidth until “on-demand” data is available. If there were enough “on-demand” data to send, all available bandwidth would be consumed, starving the application. One potentially desirable extension to this would be to limit the bandwidth usage for “on-demand” to insure this application starvation does not occur.

The flexibility of the present invention allows for varying levels of hardware/software implementation support. Moreover, the debug/trace component may be implemented purely in software, purely in hardware, or in a combination of the two. Depending on the designer's needs (silicon or software), the appropriate ratio of hardware support to software support can be determined. The bandwidth provisioning may occur in software or be controlled by hardware. Hardware support can provide implementation-specific functionality, such as internal signal node analysis/manipulation or data collection/dissemination from/to multiple asynchronous systems (collocated on the same silicon or distributed).

Moreover, the sampled state-based logic data transport solution of the present invention has a foundation that supports at least three beneficial elements: a) it is bi-directional; b) it is scalable to include or exclude one or more logic state devices or systems within a semiconductor or system; and c) it is scalable as to throughput. The sampled state based logic data transport solution allows large amounts of sampled logic data to move through the system to the logic analysis system with the minimum effect on the electronic system of the DUT. Thus, the present invention's sampled state-based logic data transport accommodates increases in speed and complexity and reduced visibility associated with electronic systems.

Thus, the present invention allows the implementer the ability to scale the amount of in-band or out-of-band sampled state-based logic data to pass through the system up to the maximum supported by the network conduit and down to nothing. Additionally, the present invention provides the ability to scale with improvements in network conduit technology. For example, the faster the network conduit, the more sampled state-based logic data can pass. Moreover, as high-speed systems continue to evolve, their network conduit's bandwidth is usually increased proportionately to facilitate the use of the high-speed system itself (i.e., a faster network conduit is part of the main feature-set of the system; bandwidth is thereby increased by necessity). The present invention accommodates such increases in bandwidth associated with the network conduit and utilizes such high-speed systems to extract sampled state-based logic at a faster rate.

Thus, the present invention's system can be used in debugging various embedded systems. For example, a semiconductor's internal bus can be sampled and logic data packets with such sampled data can be transmitted via a network channel (wherein the network channel is not dependant on synchronous or asynchronous semiconductor operation). Sampled data packets can contain multiple, asynchronous sampled data from several processes and can be transported over a network channel with varying or non-varying priority that can be determined by the semiconductor. Additionally, such data packets can contain injection or stimulus data to be injected into the network channel to excite logic signals within a sub-system of a semiconductor. The present invention can also be used to watch one or more processors un-intrusively to obtain op-code execution and flow data. Additionally, profiling (such as calculating statistics associated with such op-code execution and flow data) can also be performed based upon the trace, wherein such profiling information can be transmitted via the existing network conduit.

Conclusion

A system and method has been shown in the above embodiments for the effective implementation of a system and method for exposing state-based logic signals within an electronics system over an existing network conduit. While various preferred embodiments have been shown and described, it will be understood that there is no intent to limit the invention by such disclosure but, rather, it is intended to cover all modifications and alternate constructions falling within the spirit and scope of the invention as defined in the appended claims. For example, the present invention should not be limited by type of packetized network conduit, location of control software, choice of hardware or software implementation of bandwidth provisioning/filter, type of sampled logic data, choice of hardware or software implementation of the “on demand” embodiment, computing environment, or specific hardware associated with the network conduit, filter device, or logic analysis system.

The above enhancements are implemented in various computing environments. For example, the present invention may be implemented on a conventional IBM PC or equivalent, multi-nodal system (e.g., LAN) or networking system (e.g., Internet, WWW, wireless web). All programming and data related thereto are stored in computer memory, static or dynamic, and may be retrieved by the user in any of: conventional computer storage, display (i.e., CRT) and/or hardcopy (i.e., printed) formats. The programming of the present invention may be implemented by one skilled in the art of embedded systems.

1. An electronic embedded system, said system comprising:
a. an embedded debug/trace component sampling system-level state-based logic data; and
b. an existing network conduit packetizing and transmitting said sampled system-level state-based logic data to an external system.

2. An electronic embedded system as per claim 1, wherein said transmission is done in-band by sharing transmission bandwidth between said sampled system-level state-based logic data and application-level data associated with said embedded system.

3. An electronic embedded system as per claim 2, wherein a quality-of-service (QOS) metering scheme is implemented based upon adjusting traffic priority between said system-level state-based logic data and application-level data.

4. An electronic embedded system as per claim 1, wherein said transmission is done out-of-band by dedicating transmission bandwidth for transmitting said sampled system-level state-based data.

5. An electronic embedded system as per claim 1, wherein said system further comprises an encoder encoding said packetized data before transmission.

6. An electronic embedded system as per claim 1, wherein said pre-existing network conduit is based on any one of the following architectures: 802.3 (Ethernet), USB, ATM, SONET, Fibre-channel, Firewire or IEEE 1394, Infiniband, Bluetooth, 802.15, 802.16, or 802.17.

7. An electronic embedded system as per claim 1, wherein the amount of said sampled system-level state-based logic data is scaled linearly with bandwidth associated with said existing network conduit.

8. An electronic embedded system as per claim 1, wherein said packetized data further comprises timestamp and ordering information.

9. An electronic embedded system as per claim 1, wherein said system-level state-based logic data includes processor op-code execution and flow data.

10. An electronic embedded system as per claim 9, wherein said op-code execution and flow data is associated with a plurality of processors that are independent of or dependent on op-code instructions.

11. An electronic embedded system as per claim 1, wherein said system is scalable to include or exclude parts of said sampled system-level state-based logic data.

12. A control system for controlling an electronic system having an existing network conduit, said control system comprising:
a. an external system interface for interfacing an external system and a controller;
b. a network interface for interfacing said controller and said existing network conduit, and
c. said controller receiving, via said external system interface, control instructions from said external system to modify system-level state-based logic data associated with said electronic system, and transmitting, via said network interface, said received control instructions to said electronic system with said existing network conduit.

13. A method for transmitting packetized system-level state-based logic data associated with an electronic embedded system, said method comprising the steps of:
a. sampling system-level state-based logic data associated with an electronic embedded system;
b. packetizing said sampled system-level state-based logic data; and
c. transmitting, via an existing network conduit, said packetized data to an external system.

14. A method as per claim 13, wherein said transmission is done in-band by sharing transmission bandwidth between said sampled system-level state-based logic data and application-level data associated with said embedded system.

15. A method as per claim 14, wherein a quality-of-service (QOS) metering scheme is implemented based upon adjusting traffic priority between said system-level state-based logic data and application-level data.

16. A method as per claim 13, wherein said transmission is done out-of-band by using a dedicated transmission bandwidth for transmitting said packetized system-level state-based data.

17. A method for transmitting packetized state-based logic data associated with an electronic embedded system, as per claim 13, wherein said method further comprises the step of encoding said packetized data before transmission.

18. A method for transmitting packetized state-based logic data associated with an electronic embedded system, as per claim 13, wherein said network conduit is based on any one of the following architectures: 802.3 (Ethernet), USB, ATM, SONET, Fibre-channel, Firewire or IEEE 1394, Infiniband, Bluetooth, 802.15, 802.16, or 802.17.

19. A method for transmitting packetized state-based logic data associated with an electronic embedded system, as per claim 13, wherein the amount of said sampled logic data packets is scaled linearly with bandwidth associated with said network conduit.

20. A method for transmitting packetized state-based logic data associated with an electronic embedded system, as per claim 13, wherein said packetized data further comprises timestamp and ordering information.

21. A method for transmitting packetized state-based logic data associated with an electronic embedded system, as per claim 13, wherein said logic data packets include processor op-code execution and flow data.

22. A method for transmitting packetized state-based logic data associated with an electronic embedded system, as per claim 13, wherein said op-code execution and flow data is associated with a plurality of processors that are independent of or dependent on op-code instructions.

23. A method for transmitting packetized state-based logic data associated with an electronic embedded system, as per claim 13, wherein said method is scalable to include or exclude parts of said sampled system-level logic data.

24. A filter device for separating sampled state-based logic data from application-related data received from an electronic embedded system, said device comprising:
a. a first interface receiving packetized data from an existing network interface of said embedded system;
b. a second interface; and
c. a network traffic filter receiving said packetized data from said first interface, separating application-level data and sampled system-level state-based logic data, forwarding said application-level data via said first interface, and forwarding said system-level state-based logic data via said second interface.

25. A filter device for separating state-based logic data from application-related data received from an electronic embedded system, as per claim 24, wherein said device further comprises a decoder for decoding said received packetized data before forwarding such data to said network traffic filter.
